(19) United States
(12) Patent Application Publication
(10) Pub. No.: US 2010/0178763 A1
(43) Pub. Date: Jul. 15, 2010

(54) METHOD AND APPARATUS FOR FABRICATING SEMICONDUCTOR DEVICE

(76) Inventors: Kenji NARITA, Osaka (JP); Yoshiharu Hidaka, Osaka (JP); Koji Utaka, Hyogo (JP)

Correspondence Address: MCDERMOTT WILL & EMERY LLP, 600 13TH STREET, NW, WASHINGTON, DC, 20005-3096, US

(21) Appl. No.: 12/651,673

(22) Filed: Jan. 4, 2010

(30) Foreign Application Priority Data
Jan. 13, 2009 (JP) 2009-005069

(51) Int. Cl. H01L 21/3205; B05C 11/00; B05C 9/10

(52) U.S. Cl. 438/664; 118/722; 118/620; 257/E21.296

(57) ABSTRACT

A method for fabricating a semiconductor device includes the steps of: (a) forming an alloy film containing a precious metal on a substrate having a semiconductor layer or on a conductive film formed on the substrate; (b) heat-treating the substrate to allow the precious metal to react with silicon forming a silicide film containing the precious metal on the substrate or the conductive film; (c) removing an unreacted portion of the alloy film with a first chemical solution after the step (b); (d) forming a silicon oxide film on the top surface of the silicide film including a portion underlying a residue of the precious metal by exposing the substrate to an oxidative atmosphere; and (e) dissolving the residue of the precious metal with a second chemical solution.

### CROSS-REFERENCE TO RELATED APPLICATION

This application claims priority to Japanese Patent Application No. 2009-005069 filed on Jan. 13, 2009, the disclosure of which including the specification, the drawings, and the claims is hereby incorporated by reference in its entirety.

### BACKGROUND

The technology disclosed herein relates to a method and apparatus for fabricating a semiconductor device, and more particularly to a method for fabricating a semiconductor device including a step of removing precious metal and a fabrication apparatus used in formation of a silicide film.

In fine-line CMOS (complementary metal-oxide-semiconductor) process, there have been demands for devices with further higher performance and lower power consumption. With this being the situation, in the conventional CMOS process, NiSi and CoSi having Ni and Co as a silicide material have been used for further reduction in silicide resistance.

In the meantime, however, in the fine-line process, it is necessary to suppress silicide reaction of NiSi and CoSi for reduction in junction leakage current. For this reason, as a silicide material, alloys of Ni or Co with about 5 to 10% of Pt or Pd mixed thereto have been used. Among others, an alloy of Ni and Pt (NiPt) as a silicide material is expected to exhibit effects of improving heat resistance and reducing the junction leakage current.

In a silicide formation process, in which an alloy film is formed on a Si substrate and then subjected to thermal oxidation to allow the alloy to react with Si forming a silicide, unreacted alloy residues must be removed. For example, when an alloy of Ni and Pt (NiPt) is used as a silicide material, a highly oxidative acid such as a mixed solution of sulfuric acid and hydrogen peroxide is used for removing unreacted NiPt after silicide formation (see Japanese Patent Publication No. P2002-124487, for example).

FIGS. 12A and 12B are views showing a conventional silicide formation process. In the step shown in FIG. 12A, after preparation of a semiconductor substrate 121 made of silicon, the top surface of which is partly exposed as a silicide formation region, an insulating film 122 is formed on the portion of the semiconductor substrate 121 other than the silicide formation region. Thereafter, NiPt 123 as a silicide material is deposited on the entire surface of the resultant semiconductor substrate 121. Thermal oxidation is then performed to form a silicide layer 124 made of mixed crystal of NiSi and NiPtSi in the silicide formation region. Note that the mixed crystal of NiSi and NiPtSi is hereinafter called NiPtSi collectively.

In the step shown in FIG. 12B, unreacted NiPt 123 is removed while only NiPtSi is left behind. In this step, the unreacted NiPt 123 is removed using a mixed solution 125 of sulfuric acid and hydrogen peroxide.

Using a highly oxidative acid like the mixed solution of sulfuric acid and hydrogen peroxide for removal of the unreacted NiPt 123 in the silicide formation process, Ni may be dissolved. However, Pt, which is low in chemical reactivity, fails to dissolve but remains on the semiconductor substrate. To prevent Pt from remaining, therefore, aqua regia (solution containing nitric acid and hydrochloric acid) having oxidative power stronger than the mixed solution 125 may be used in place of the mixed solution 125 (see Japanese Patent Publication No. 2008-118088, for example).

### SUMMARY

However, the inventors of the present invention has found that, when aqua regia having strong oxidative power is used to dissolve and remove Pt residues, it also allows the dissolution reaction to proceed in the silicided NiPtSi portion because hydrochloric acid in the aqua regia is highly corrosive also to NiSi, and this may cause resistance anomaly of the silicide layer. This phenomenon occurs for the following reason. An oxide film, formed on NiSi at the removal of unreacted Ni with a chemical solution such as a mixed solution of sulfuric acid and hydrogen peroxide, fails to be formed immediately under Pt residues since the Pt residues block formation of the oxide film. Therefore, at the time of removal of the Pt residues with aqua regia, NiSi under the Pt residues will be etched away together with the Pt residues. As a result, the surface of the silicide film is roughened.

According to illustrative embodiments of the present invention, corrosion of the surface of the silicide film with a chemical solution such as aqua regia is suppressed, and hence a good Pt-containing silicide film can be formed.

To solve the above problem, the first method for fabricating a semiconductor device of an example of the present invention includes the steps of: (a) forming an alloy film containing a precious metal on a substrate having a semiconductor layer containing silicon or on a conductive film containing silicon formed on the substrate; (b) heat-treating the substrate after the step (a) to allow the precious metal to react with silicon forming a silicide film containing the precious metal on the substrate or the conductive film; (c) removing an unreacted portion of the alloy film with a first chemical solution after the step (b); (d) forming a silicon oxide film on the top surface of the silicide film including a portion underlying a residue of the precious metal after the step (c); and (e) dissolving the residue of the precious metal with a second chemical solution after the step (d).

According to the method described above, a silicon oxide film is formed on the top surface of the silicide film including a portion thereof underlying a residue of a precious metal in the step (d). The silicide film is therefore prevented from being corroded with the second chemical solution at the time of dissolution of the residue of the precious metal in the step (e). Hence, a semiconductor device with high reliability can be fabricated.

In the step (d), the silicon oxide film is preferably formed by exposing the substrate to an oxidative atmosphere.

In the step (d), the oxidative atmosphere is preferably formed using oxygen plasma, a mixed gas of vapor and hydrogen, or ozone gas.

The second method for fabricating a semiconductor device of an example of the present invention includes the steps of: (a) forming an alloy film containing a precious metal on a substrate having a semiconductor layer containing silicon or on a conductive film containing silicon formed on the substrate; (b) heat-treating the substrate after the step (a) to allow the precious metal to react with silicon forming a silicide film containing the precious metal on the substrate or the conductive film; (c) irradiating the substrate with light selected from the group consisting of infrared light, visible light, and ultraviolet light singly or in combination; (d) removing an unreacted portion of the alloy film with a first chemical solution after the step (c), and also forming a silicon oxide film on the top surface of the silicide film including a portion underlying a residue of the precious metal; and (e) dissolving the residue of the precious metal with a second chemical solution after the step (d).

According to the method described above, since the silicide film has been activated in the step (c), the silicon oxide film can be formed also on a portion of the silicide film underlying a residue of a precious metal in the step (d). Hence, the precious metal residue can be removed without causing corrosion of the silicide layer in the step (e).

The precious metal may be platinum, the alloy film may be a nickel-platinum film, the first chemical solution may be a mixed solution of a sulfuric acid system solution and an oxidant, and the second chemical solution may be a mixed solution of a hydrochloric acid system solution and an oxidant.

The first chemical solution is preferably a solution selected from the group consisting of a mixed solution of sulfuric acid and hydrogen peroxide, a mixed solution of sulfuric acid and ozone water, and an electrolyzed sulfuric acid solution.

The second chemical solution may be a solution selected from the group consisting of a mixed solution of nitric acid and hydrochloric acid, a mixed solution of hydrochloric acid and hydrogen peroxide, a mixed solution of hydrochloric acid and ozone water, a solution of hydrochloric acid mixed with potassium permanganate, a solution of hydrochloric acid mixed with chromium trioxide, a solution of hydrochloric acid mixed with potassium chlorate, a solution of hydrochloric acid mixed with osmium tetraoxide, and dilute solutions of these solutions.

In the step (d), also, the substrate may be irradiated with the light selected from the group consisting of infrared light, visible light, and ultraviolet light singly or in combination.

The first apparatus for fabricating a semiconductor device of an example of the present invention includes: a first chamber configured to feed a first chemical solution to a substrate to remove an unreacted portion of an alloy film formed on the substrate; a second chamber configured to expose the substrate to an oxidative atmosphere to form a silicon oxide film on the top surface of a silicide film formed on the substrate; a third chamber configured to feed a second chemical solution to the substrate to dissolve a residue of a precious metal on the top surface of the silicide film; and a conveyer section configured to convey the substrate to the first chamber, the second chamber, and the third chamber.

According to the apparatus described above, treatments in the chambers can be performed in succession. Hence, formation of the silicide film and removal of precious metal residues can be performed efficiently.

The first chamber and the second chamber may be the same chamber.

The second apparatus for fabricating a semiconductor device of an example of the present invention includes: a light irradiation section configured to irradiate a substrate with light selected from the group consisting of infrared light, visible light, and ultraviolet light singly or in combination; a first chamber configured to feed a first chemical solution to the substrate to remove an unreacted portion of an alloy film formed on the substrate and also form a silicon oxide film on the top surface of a silicide film on the substrate; a second chamber configured to feed a second chemical solution to the substrate to dissolve a residue of a precious metal on the top surface of the silicide film; and a conveyer section configured to convey the substrate to the first chamber and the second chamber.

According to the apparatus described above, treatments in the chambers can be performed in succession. Hence, formation of the silicide film and removal of precious metal residues can be performed efficiently.

The light irradiation section may be placed in the first chamber.

As described above, according to the method and apparatus for fabricating a semiconductor device of an example of the present invention, an oxide film is formed on the silicide film including portions thereof underlying Pt residues before removal of the Pt residues with the second chemical solution. Hence, corrosion of the silicide film can be suppressed in the step of dissolving the precious metal residues. As a result, a good silicide film containing a precious metal can be formed.

### BRIEF DESCRIPTION OF THE DRAWINGS

FIGS. 1A and 1B are cross-sectional views showing a method for fabricating a semiconductor device of Embodiment 1 of the present invention.

FIGS. 2A and 2B are cross-sectional views showing the method for fabricating a semiconductor device of Embodiment 1.

FIG. 3 is a view showing a SEM image of the top surface of a NiPtSi film after treated with SPM.

FIG. 4 is a cross-sectional view schematically showing the top surface of the NiPtSi film after treated with SPM.

FIG. 5 is a view showing a SEM image of the top surface of the NiPtSi film observed when treated by a conventional method.

FIG. 6 is a cross-sectional view schematically showing a semiconductor substrate observed when treated by the method of Embodiment 1.

FIG. 7 is a view showing a SEM image of the top surface of the NiPtSi film observed when treated by the method of Embodiment 1.

FIG. 8 is a schematic view showing a fabrication apparatus for executing the method for fabricating a semiconductor device of Embodiment 1.

FIG. 9 is a cross-sectional view schematically showing a semiconductor substrate observed when treated by a method of Embodiment 2 of the present invention.

FIG. 10 is a view showing a SEM image of the top surface of a NiPtSi film observed when treated by the method of Embodiment 2.

FIG. 11 is a schematic view showing a fabrication apparatus for executing the method for fabricating a semiconductor device of Embodiment 2.

FIGS. 12A and 12B are views showing a conventional silicide formation process.

### DETAILED DESCRIPTION

### Embodiment 1

An example of a method and apparatus for fabricating a semiconductor device of Embodiment 1 of the present invention will be described hereinafter with reference to the relevant drawings.

—Method for Fabricating Semiconductor Device—

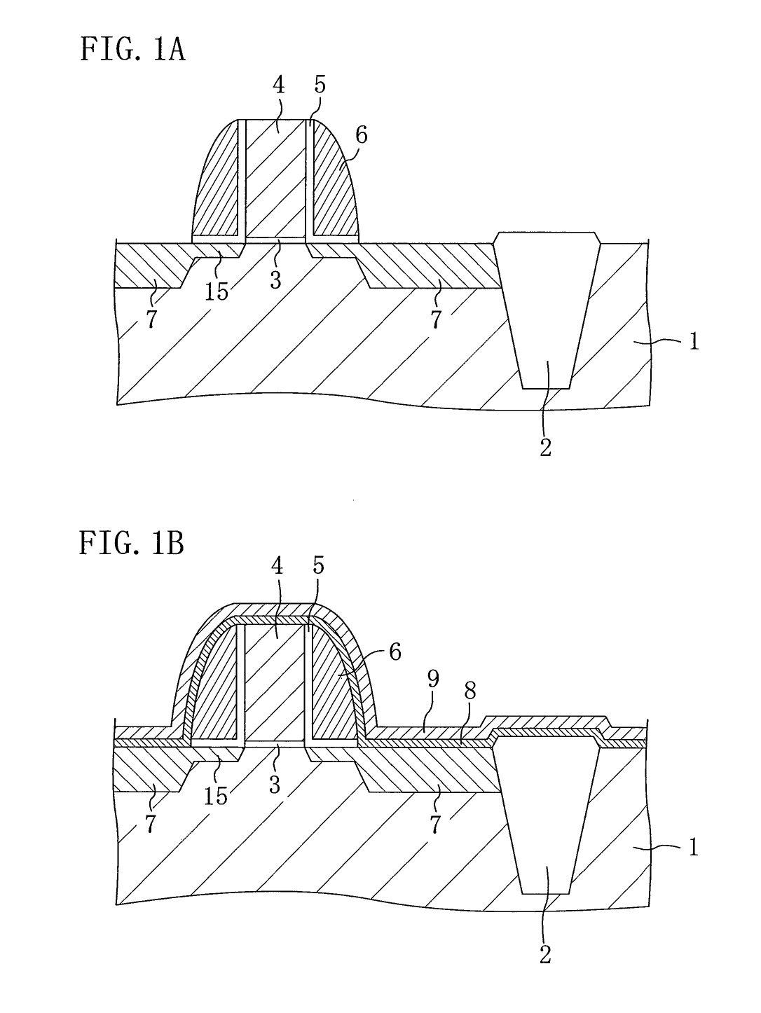

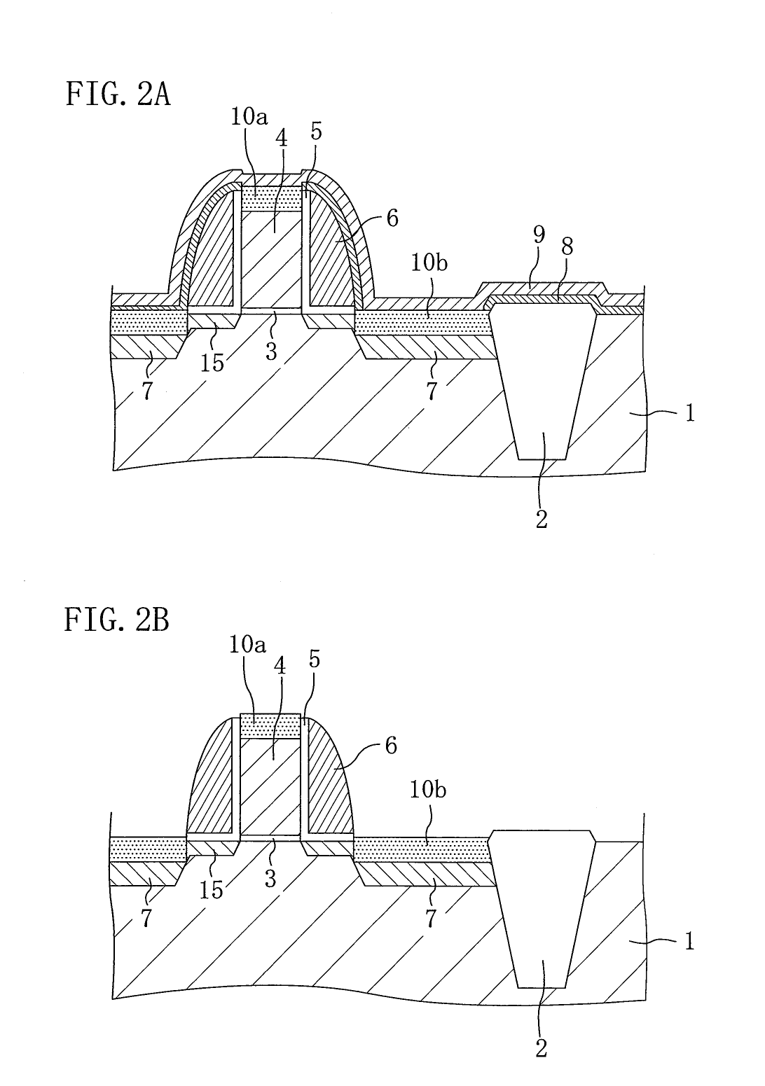

FIGS. 1A, 1B, 2A, and 2B are cross-sectional views showing a method for fabricating a semiconductor device of Embodiment 1 of the present invention.

First, in the step shown in FIG. 1A, an element isolation region 2 is formed in a semiconductor substrate 1 made of silicon by shallow trench isolation (STI) and the like. A gate insulating film 3 made of a silicon oxide film having a thickness of 2 nm is then formed on a portion of the semiconductor substrate 1 between the adjacent element isolation regions 2 by thermal oxidation. Thereafter, a polysilicon film having a thickness of 100 nm is formed on the entire surface of the resultant semiconductor substrate 1 by chemical vapor deposition (CVD), and then a dopant impurity is introduced in the polysilicon film by ion implantation. When an NMOS transistor is to be formed, phosphorus is implanted as an n-type dopant impurity under the conditions of an accelerating voltage of 15 keV and a dose of 1×10¹⁶ cm⁻². When a PMOS transistor is to be formed, boron is implanted as a p-type dopant impurity under the conditions of an accelerating voltage of 5 keV and a dose of 5×10¹⁵ cm⁻², for example. Thereafter, the polysilicon film is patterned by photolithography and dry etching, to form a gate electrode (conductive film) 4 made of the polysilicon film.

Using the gate electrode 4 as a mask, a dopant impurity is introduced in regions of the semiconductor substrate 1 located on both sides of the gate electrode 4 by ion implantation. When an NMOS transistor is to be formed, arsenic is implanted as an n-type dopant impurity under the conditions of an accelerating voltage of 2 keV and a dose of 1×10¹⁵ cm⁻², for example. When a PMOS transistor is to be formed, boron is implanted as a p-type dopant impurity under the conditions of an accelerating voltage of 0.5 keV and a dose of 3×10¹⁵ cm⁻², for example. With this implantation, shallow impurity diffusion regions that are to be extension regions 15 of source/drain diffusion layers are formed.

Thereafter, a silicon oxide film having a thickness of 10 nm and a silicon nitride film having a thickness of 50 nm are formed on the entire surface of the resultant semiconductor substrate 1 by CVD. The silicon oxide film and the silicon nitride film are then subjected to anisotropic etching by reactive ion etching (RIE), to form sidewall insulating films 5 made of the silicon oxide film and sidewall insulating films 6 made of the silicon nitride film on the sidewalls of the gate electrode 4. Using the gate electrode 4 and the sidewall insulating films 5 and 6 as a mask, a dopant impurity is introduced in regions of the semiconductor substrate 1 located on both sides of the gate electrode 4 and the sidewall insulating films 5 and 6 by ion implantation. When an NMOS transistor is to be formed, arsenic is implanted as an n-type dopant impurity under the conditions of an accelerating voltage of 20 keV and a dose of 5×10¹⁵ cm⁻², for example. When a PMOS transistor is to be formed, boron is implanted as a p-type dopant impurity under the conditions of an accelerating voltage of 5 keV and a dose of 5×10¹⁵ cm⁻², for example. With this implantation, deep impurity diffusion regions of the source/drain diffusion layers are formed. The dopant impurities introduced in the impurity diffusion regions are then activated under predetermined thermal treatment, thereby forming source/drain diffusion layers 7.

In the step shown in FIG. 1B, a NiPt (alloy) film 8 having a thickness of 7 to 15 nm, for example, is formed on the entire surface of the resultant semiconductor substrate 1 by sputtering using a platinum (Pt) added nickel (Ni) target, for example. The Pt composition of the target is set at 2 to 10 atom %, for example. A protection film 9 made of a TiN film having a thickness of 5 to 30 nm, for example, is then formed on the NiPt film 8 by sputtering, for example, for preventing oxidation of the NiPt film 8.

In the step shown in FIG. 2A, rapid thermal annealing (RTA) is performed as thermal treatment for silicide formation at 200 to 400° C. for 30 seconds, for example. This allows NiPt of the NiPt film 8 to react with Si in the top portion of the gate electrode 4 to form a NiPtSi film 10a on the gate electrode 4, and react with Si in the top portions of the source/drain diffusion layers 7 to form NiPtSi films 10b on the source/drain diffusion layers 7.

In the step shown in FIG. 2B, unreacted portions of the protection film 9 and the NiPt film 8 are selectively removed by wet etching using a comparatively high temperature chemical solution containing an oxidant.

As the oxidant-containing chemical solution, a sulfuric acid-hydrogen peroxide mixture (SPM) solution, for example, is used. Note that the concentrations of sulfuric acid and hydrogen peroxide in the SPM solution are respectively 50 to 90 vol % and 10 to 50 vol %, for example.

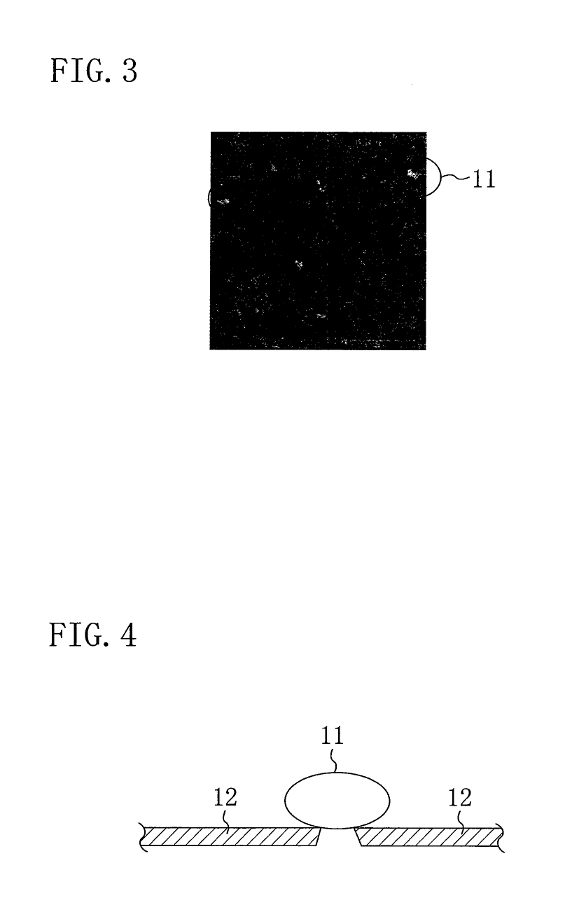

Using the SPM solution, however, as shown in FIGS. 3 and 4, while the protection film 9 made of a TiN film and Ni in the NiPt film 8 can be dissolved, Pt cannot be dissolved. Hence, Pt particles 11 remain on the semiconductor substrate 1, the element isolation region 2, and the gate electrode 4. FIG. 3 shows a SEM image of the top surface of the semiconductor substrate, from which it is found that Pt particles 11 remain on the NiPtSi films 10a and 10b. To dissolve these remaining Pt particles 11, a strong acid such as aqua regia (nitric acid:hydrochloric acid=1:3 in volume) must be used. However, chlorine in the aqua regia is corrosive also to Ni in the NiPtSi films 10a and 10b, turning Ni to its nitride ions, and hence the NiPtSi films 10a and 10b as the silicide films are dissolved. Note that 60 wt % nitric acid and 36 wt % hydrochloric acid, for example, are used in preparation of aqua regia.

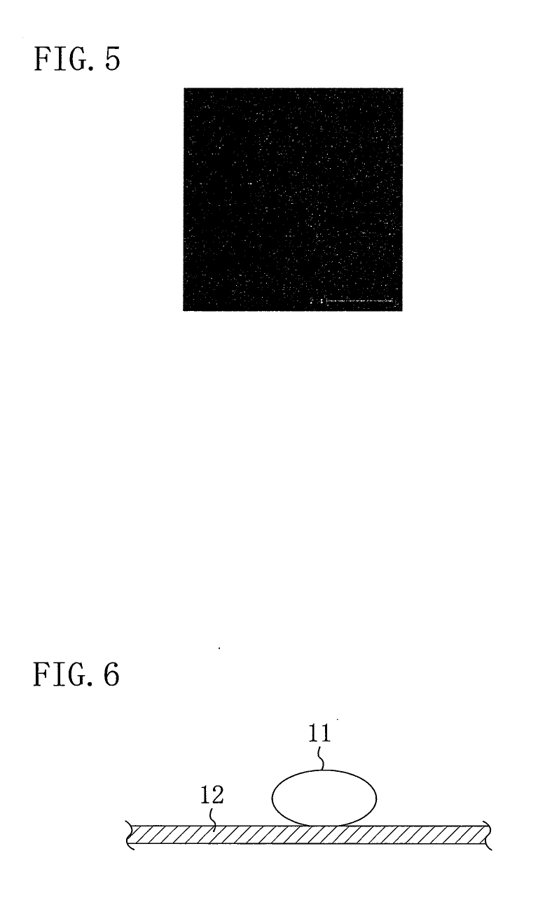

In the meantime, in FIG. 4 showing the NiPtSi surface state after the treatment with the SPM solution, while a silicon oxide film 12 is formed on the exposed portion of the top surface of the NiPtSi film 10a, 10b because the SPM solution has oxidative power, no silicon oxide film is formed on the portion under the remaining Pt particle 11. The silicon oxide film 12 does not dissolve in aqua regia. Therefore, if the Pt particles 11 are dissolved and removed with aqua regia in this state, the portions of the NiPtSi films 10a and 10b having the Pt particles 11 formed thereon will be dissolved while the other portions thereof having no Pt particles will not be dissolved, as is found from FIG. 5 showing a SEM image of the NiPtSi film 10a, 10b after the treatment with aqua regia.

To address the above problem, in the method of this embodiment, oxygen plasma treatment is performed after the SPM treatment, to expose the top surfaces of the NiPtSi films 10a and 10b to an oxidative atmosphere intentionally. With this treatment, the silicon oxide film 12 can be formed also on the portions underlying the Pt particles 11 like the other portions. In a specific example, 30-second oxygen plasma treatment at a temperature of 150° C. to 200° C. is performed by irradiating the NiPtSi films 10a and 10b with microwave of 2000 W to 3000 W while feeding oxygen gas at 2000 to 3000 mL/min (sccm) under a pressure of 250 Pa to 300 Pa

FIG. 6 is a cross-sectional view schematically showing the surface state of the NiPtSi film after the oxygen plasma treatment described above. As shown in FIG. 6, the uniform silicon oxide film 12 having a thickness of about 2 to 3 nm is formed also on the portions of the NiPtSi films 10a and 10b underlying the Pt particles 11 by the oxygen plasma treatment.

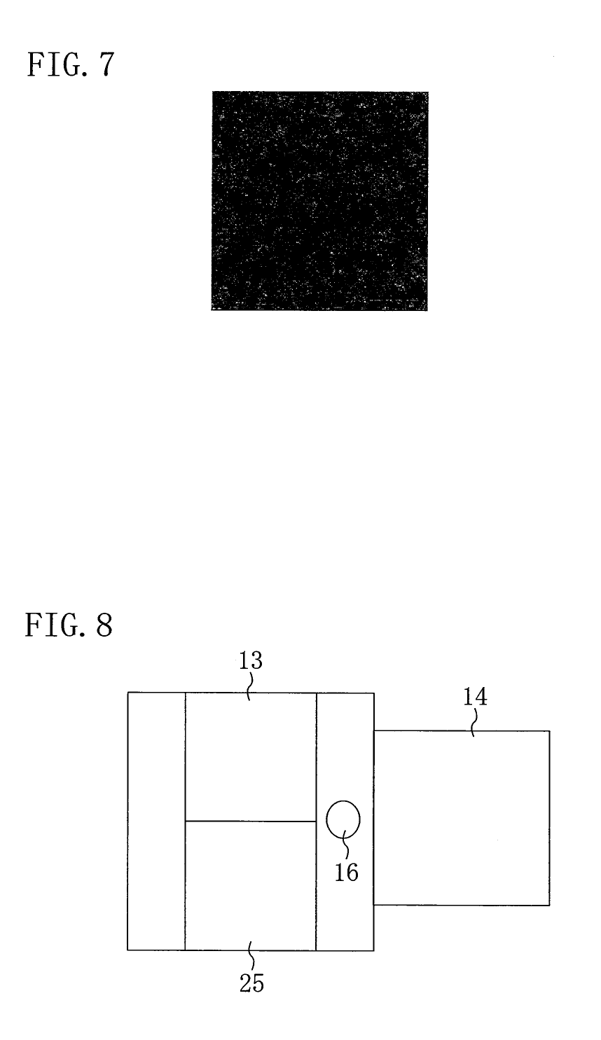

FIG. 7 is a view showing a SEM image of the top surface of the NiPtSi film subjected to the oxygen plasma treatment described above after the SPM treatment and then subjected to 120-second treatment with aqua regia to remove Pt particles. From FIG. 7, it is found that according to the method of this embodiment, the NiPtSi films 10a and 10b are formed in a good state with no dissolution observed at the portions of the NiPtSi films 10a and 10b on which the Pt particles 11 have once existed.

As the oxidative atmosphere for the oxygen plasma treatment, a vapor/hydrogen mixed gas may be used. Using this mixed gas, since the silicon oxidation rate becomes greater as the vapor concentration is higher, the uniform silicon oxide film 12 can be formed on the NiPtSi films 10a and 10b in a shorter time.

As another example of the oxidative atmosphere, thermal treatment at 200° C. in an atmospheric-pressure oxygen atmosphere containing an oxidative gas made of ozone may be made. With this thermal treatment, also, the uniform silicon oxide film 12 can be formed on the NiPtSi films 10a and 10b in a short time.

As described above, according to the method of this embodiment, the uniform silicon oxide film 12 having a thickness of about 2 to 3 nm can be formed on the entire surfaces of the NiPtSi films 10a and 10b including the portions thereof under the Pt particles 11. This can suppress dissolution and corrosion of the NiPtSi films 10a and 10b at the time of dissolution of the Pt particles 11 with aqua regia. At the same time, radicals of PtO and PtOH are formed on the surfaces of the Pt particles during the oxygen plasma treatment, activating the Pt particles 11. This can improve the Pt dissolution property of the aqua regia.

In this embodiment, the NiPt alloy film was used as the metal film to be silicided as an example. This embodiment is not limited to this, but can also be implemented similarly using a CoPt film and a TiPt film, for example.

In the method of this embodiment, SPM was used as the solution for removing unreacted NiPt. This embodiment is not limited to this, but a similar effect can also be obtained by using a chemical solution of a sulfuric acid system with an oxidant added thereto, such as a mixed solution of sulfuric acid and ozone water (H₂SO₄: O₃=1 to 5:1; 80° C. to 160° C.) and an electrolyzed sulfuric acid solution (80° C. to 100° C.). The mixed solution of sulfuric acid and ozone water is specifically a mixture of 98 wt % sulfuric acid and 20 ppm ozone water.

In the method of this embodiment, aqua regia (nitric acid:hydrochloric acid=1:3 in volume) was used as the solution for dissolving Pt particles. This embodiment is not limited to this, but a solution of the aqua regia diluted with water up to seven-fold is also applicable. In addition, a chemical solution containing hydrochloric acid and an oxidant can be used. For example, a similar effect can be obtained using the following solutions: a mixed solution of hydrochloric acid and hydrogen peroxide (HCl: H₂O₂=3 to 5:1; treatment temperature: 40° C. to 70° C.), a mixed solution of hydrochloric acid and ozone water (HCl: O₃=3 to 5:1; treatment temperature: 40° C. to 70° C.), a solution of hydrochloric acid mixed with potassium permanganate (KMnO₄; 1 to 7 wt %; treatment temperature: 40° C. to 70° C.), a solution of hydrochloric acid mixed with chromium trioxide (CrO₃; 1 to 5 wt %; treatment temperature: 40° C. to 70° C.), a solution of hydrochloric acid mixed with potassium chlorate (KClO₃; 1 to 7 wt %; treatment temperature: 40° C. to 70° C.), a solution of hydrochloric acid mixed with osmium tetraoxide (OsO₄; 1 to 6 wt %; treatment temperature: 40° C. to 70° C.), and dilute solutions of the above solutions diluted with water one- to seven-fold. The concentration of hydrochloric acid used in the preparation of the above solutions is 36 wt %, for example. The concentration of hydrogen peroxide is 31 wt %, and that of ozone water is 20 ppm.

—Apparatus for Fabricating Semiconductor Device—

FIG. 8 is a schematic plan view of a fabrication apparatus used in execution of the method for fabricating a semiconductor device of this embodiment, as viewed from top.

The fabrication apparatus includes: an SPM treatment chamber 13 for removing unreacted NiPt after silicide formation; a surface oxidation chamber 14 for oxidizing the entire top surface of the NiPtSi film, including portions of the NiPtSi film on which Pt particles remain, after the NiPt removal; an aqua regia treatment chamber 25 for removing the Pt particles remaining on the NiPtSi film; and a conveyer arm (conveyer section) 16 for conveying a wafer to the SPM treatment chamber 13, the surface oxidation chamber 14, and the aqua regia treatment chamber 25. The SPM treatment chamber 13 and the aqua regia treatment chamber 25 are adjacent to each other, and are adjacent to the surface oxidation chamber 14 via the conveyer arm 16. The conveyer arm 16 is rotatable in the plane. A nozzle for feeding SPM to the wafer is provided in the SPM treatment chamber 13, and a nozzle for feeding aqua regia to the wafer is provided in the aqua regia treatment chamber 25. This fabrication apparatus is a tree-type treatment apparatus.

Using the fabrication apparatus described above, a wafer can be treated in succession without being left untreated after each treatment step. Note that the surface oxidation chamber 14 and the aqua regia treatment chamber 25 may be configured so that the two treatment steps can be executed in the same chamber.

As described above, according to the method and apparatus for fabricating a semiconductor device of this embodiment, the NiPtSi film having Pt particles remaining thereon is exposed to an oxidative atmosphere, to form the uniform silicon oxide film 12 having a thickness of about 2 to 3 nm intentionally also on the portions of the NiPtSi film under the Pt particles. Hence, dissolution and corrosion of the NiPtSi film can be suppressed at the time of dissolution of the Pt particles with the aqua regia. As a result, a good platinum-containing silicide film, the top surface of which is suppressed from corrosion with the aqua regia having Pt dissolving power, can be formed.

In this embodiment, portions of the top surface of the NiPtSi film underlying Pt particles were oxidized by exposing the NiPtSi film to an oxidative atmosphere to form the silicon oxide film 12, as an example. Alternatively, portions of the top surface of the NiPtSi film underlying Pt particles may be oxidized in another way. For example, the top portion of the NiPtSi film may be oxidized in a dry atmosphere other than the oxidative atmosphere, or the oxidation may be made using an oxidative chemical solution other than SPM.

### Embodiment 2

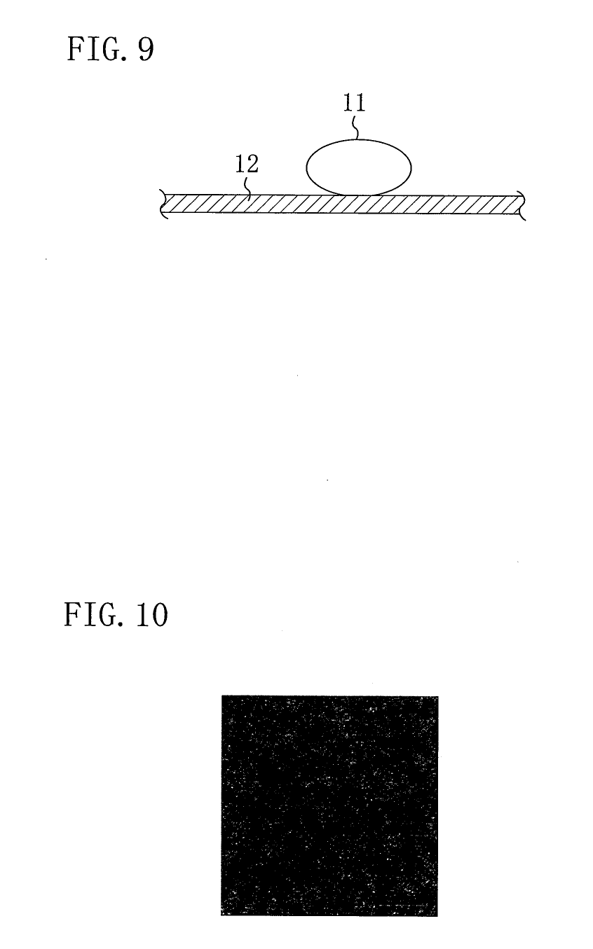

FIG. 9 is a cross-sectional view schematically showing a semiconductor substrate observed when treated by a method of Embodiment 2 of the present invention. FIG. 10 is a view showing a SEM image of the top surface of a NiPtSi film observed when treated by the method of Embodiment 2. The first half of the method for fabricating a semiconductor device of this embodiment is the same as that of the fabrication method of Embodiment 1 described above with reference to FIGS. 1 to 5. Description of this part of the method will therefore be omitted in this embodiment.

In the method of Embodiment 1, oxygen plasma treatment was performed after the SPM treatment to expose the top surfaces of the NiPtSi films 10a and 10b to an oxidative atmosphere intentionally. In the method of this embodiment, strong light irradiation is performed immediately before the SPM treatment to cause instantaneous thermal activation of the semiconductor substrate 1 and hence improve the oxidative power of SPM against the top surfaces of the NiPtSi films 10a and 10b. As the strong light, any of infrared light, visible light, and ultraviolet light, singly or in combination, may be used. Typically, light emitted from any of a halogen lamp, a metal halide lamp, a xenon arc lamp, a carbon arc lamp, a high-pressure sodium lamp, and a high-pressure mercury lamp may be used. Specifically, a lamp light source is turned on for one to ten seconds immediately before the SPM treatment to perform the above strong light irradiation, thereby to obtain the effect of improving the oxidative power of SPM against the NiPtSi films 10a and 10b.

FIG. 9 shows the surface state of the NiPtSi film after the strong light irradiation, indicating that the uniform silicon oxide film 12 having a thickness of about 2 to 3 nm can be formed also on the portion of the top surface of the NiPtSi film 10a, 10b underlying the Pt particle 11 by the strong light irradiation.

FIG. 10 shows a surface SEM image subjected to the strong light irradiation described above immediately before the SPM treatment and then subjected to 120-second treatment with aqua regia to remove Pt particles. It is found from this that according to the method of this embodiment, the NiPtSi films 10a and 10b are formed in a good state with no dissolution observed at the portions of the NiPtSi films 10a and 10b on which the Pt particles 11 have once existed.

The strong light irradiation is preferably performed before start of the SPM treatment, but may also be performed continuously during the SPM treatment. With this continuous treatment, dissolution of NiPt and activation of the Pt particles 11 can be performed while an oxide film is being formed on the top surface of the NiPtSi films 10a and 10b. Radicals of PtO and PtOH are formed on the surfaces of the Pt particles 11 with SPM, activating the Pt particles 11, and this can improve the Pt dissolution property of aqua regia.

In this embodiment, the NiPt alloy film was used as the metal film to be silicided as an example. This embodiment is not limited to this, but a similar effect to that described above can be obtained by using a CoPt film and a TiPt film, for example, in place of the NiPt film.

In the method of this embodiment, SPM was used as the solution for removing unreacted NiPt. This embodiment is not limited to this, but a similar effect can also be obtained by using a chemical solution of a sulfuric acid system with an oxidant added thereto, such as a mixed solution of sulfuric acid and ozone water (H₂SO₄: O₃=1 to 5:1; treatment temperature: 80° C. to 160° C.) and an electrolyzed sulfuric acid solution (80° C. to 100° C.).

In the method of this embodiment, aqua regia (nitric acid:hydrochloric acid=1:3 in volume) was used as the solution for dissolving Pt particles. This embodiment is not limited to this, but a dilute solution of the aqua regia diluted with water up to seven-fold is also applicable. In addition, a chemical solution containing hydrochloric acid and an oxidant can be used. For example, a similar effect can be obtained using the following solutions: a mixed solution of hydrochloric acid and hydrogen peroxide (HCl: H₂O₂=3 to 5:1; treatment temperature: 40° C. to 70° C.), a mixed solution of hydrochloric acid and ozone water (HCl: O₃=3 to 5:1; treatment temperature: 40° C. to 70° C.), a solution of hydrochloric acid mixed with potassium permanganate (KMnO₄; 1 to 7 wt %; treatment temperature: 40° C. to 70° C.), a solution of hydrochloric acid mixed with chromium trioxide (CrO₃; 1 to 5 wt %; treatment temperature: 40° C. to 70° C.), a solution of hydrochloric acid mixed with potassium chlorate (KClO₃; 1 to 7 wt %; treatment temperature: 40° C. to 70° C.), a solution of hydrochloric acid mixed with osmium tetraoxide (OsO₄; 1 to 6 wt %; treatment temperature: 40° C. to 70° C.), and dilute solutions of the above solutions diluted with water one- to seven-fold.

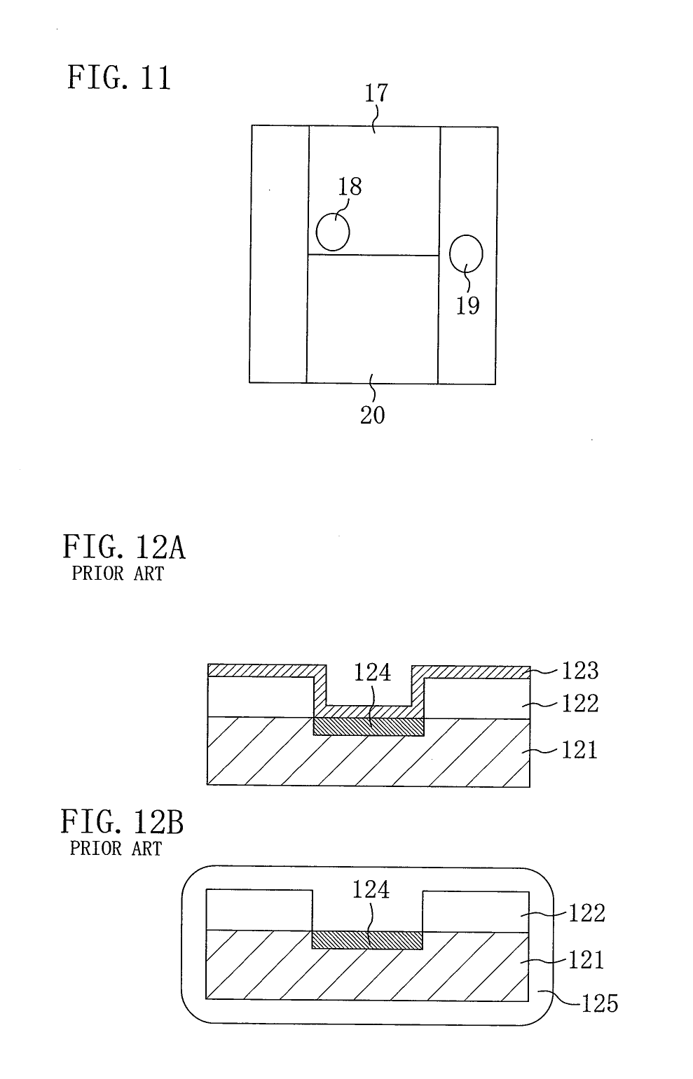

FIG. 11 is a schematic view showing a fabrication apparatus for executing the method for fabricating a semiconductor device of this embodiment.

The fabrication apparatus includes: a SPM treatment chamber 17 for removing unreacted NiPt after silicide formation; a strong light irradiation unit (light irradiation section) 18 placed at an end of the SPM treatment chamber 17 (as viewed from the top); an aqua regia treatment chamber 20 for removing Pt particles remaining on the NiPtSi film; and a conveyer arm 19 for conveying a wafer to the SPM treatment chamber 17 and the aqua regia treatment chamber 20. The SPM treatment chamber 17 and the aqua regia treatment chamber 20 are adjacent to each other. The strong light irradiation unit 18 is surface-treated with a fluorine resin and the like to be resistive to the chemical solution atmosphere. Using this fabrication apparatus, a wafer can be treated in succession without being left untreated after each treatment step.

The strong light irradiation unit 18 may be placed in a light irradiation chamber or in the SPM treatment chamber 17.

As described above, according to the method and apparatus for fabricating a semiconductor device of this embodiment, strong light irradiation is performed at least immediately before the SPM treatment to cause instantaneous thermal activation of the semiconductor substrate 1 and hence improve the oxidative power of SPM against the top surfaces of the NiPtSi films 10a and 10b. With this treatment, the uniform silicon oxide film 12 having a thickness of about 2 to 3 nm can be formed intentionally also on the portions of the NiPtSi film underlying the Pt particles 11. Hence, dissolution and corrosion of the NiPtSi films 10a and 10b can be suppressed at the time of dissolution of the Pt particles 11 with aqua regia. As a result, with the silicide surface being prevented from corrosion with aqua regia having Pt dissolving power, a good platinum-containing silicide film can be formed, in which heat resistance improves and unnecessary metal diffusion is retarded.

In the semiconductor devices of the embodiments described above, an SOI substrate having a silicon-containing semiconductor layer or the like may be used in place of the semiconductor substrate.

The method of Embodiment 1 and the method of Embodiment 2 may be combined without departing from the spirit of the present invention. Specifically, strong light irradiation may be performed before the treatment with the SPM solution, and after the SPM treatment, a silicon oxide film may be formed on the top surface of the silicide film in an oxidative atmosphere.

As described above, the method and apparatus for fabricating a semiconductor device of an example of the present invention are useful for fabrication of a semiconductor device having a silicide film containing a precious metal such as Pt.

Given the variety of embodiments of the present invention just described, the above description and illustrations show not be taken as limiting the scope of the present invention defined by the claims.

While the invention has been particularly shown and described with reference to the preferred embodiments thereof, it will be understood by those skilled in the art that various changes in form and details may be made without departing from the spirit and scope of the invention. It is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a semiconductor device, comprising the steps of:
(a) forming an alloy film containing a precious metal on a substrate having a semiconductor layer containing silicon or on a conductive film containing silicon formed on the substrate;
(b) heat-treating the substrate after the step (a) to allow the precious metal to react with silicon forming a silicide film containing the precious metal on the substrate or the conductive film;
(c) removing an unreacted portion of the alloy film with a first chemical solution after the step (b);
(d) forming a silicon oxide film on the top surface of the silicide film including a portion underlying a residue of the precious metal after the step (c); and
(e) dissolving the residue of the precious metal with a second chemical solution after the step (d).

2. The method of claim 1, wherein in the step (d), the silicon oxide film is formed by exposing the substrate to an oxidative atmosphere.

3. The method of claim 2, wherein in the step (d), the oxidative atmosphere is formed using oxygen plasma, a mixed gas of vapor and hydrogen, or ozone gas.

4. A method for fabricating a semiconductor device, comprising the steps of:
(a) forming an alloy film containing a precious metal on a substrate having a semiconductor layer containing silicon or on a conductive film containing silicon formed on the substrate;
(b) heat-treating the substrate after the step (a) to allow the precious metal to react with silicon forming a silicide film containing the precious metal on the substrate or the conductive film;
(c) irradiating the substrate with light selected from the group consisting of infrared light, visible light, and ultraviolet light singly or in combination;
(d) removing an unreacted portion of the alloy film with a first chemical solution after the step (c), and also forming a silicon oxide film on the top surface of the silicide film including a portion underlying a residue of the precious metal; and
(e) dissolving the residue of the precious metal with a second chemical solution after the step (d).

5. The method of claim 1, wherein the precious metal is platinum, the alloy film is a nickel-platinum film, the first chemical solution is a mixed solution of a sulfuric acid system solution and an oxidant, and the second chemical solution is a mixed solution of a hydrochloric acid system solution and an oxidant.

6. The method of claim 5, wherein the first chemical solution is a solution selected from the group consisting of a mixed solution of sulfuric acid and hydrogen peroxide, a mixed solution of sulfuric acid and ozone water, and an electrolyzed sulfuric acid solution.

7. The method of claim 5, wherein the second chemical solution is a solution selected from the group consisting of a mixed solution of nitric acid and hydrochloric acid, a mixed solution of hydrochloric acid and hydrogen peroxide, a mixed solution of hydrochloric acid and ozone water, a solution of hydrochloric acid mixed with potassium permanganate, a solution of hydrochloric acid mixed with chromium trioxide, a solution of hydrochloric acid mixed with potassium chlorate, a solution of hydrochloric acid mixed with osmium tetraoxide, and dilute solutions of these solutions.

8. The method of claim 4, wherein in the step (d), also, the substrate is irradiated with the light selected from the group consisting of infrared light, visible light, and ultraviolet light singly or in combination.

9. An apparatus for fabricating a semiconductor device, comprising:
a first chamber configured to feed a first chemical solution to a substrate to remove an unreacted portion of an alloy film formed on the substrate;
a second chamber configured to expose the substrate to an oxidative atmosphere to form a silicon oxide film on the top surface of a silicide film formed on the substrate;
a third chamber configured to feed a second chemical solution to the substrate to dissolve a residue of a precious metal on the top surface of the silicide film; and
a conveyer section configured to convey the substrate to the first chamber, the second chamber, and the third chamber.

10. The apparatus of claim 9, wherein the first chamber and the second chamber are the same chamber.

11. An apparatus for fabricating a semiconductor device, comprising:
a light irradiation section configured to irradiate a substrate with light selected from the group consisting of infrared light, visible light, and ultraviolet light singly or in combination;
a first chamber configured to feed a first chemical solution to the substrate to remove an unreacted portion of an alloy film formed on the substrate and also form a silicon oxide film on the top surface of a silicide film on the substrate;
a second chamber configured to feed a second chemical solution to the substrate to dissolve a residue of a precious metal on the top surface of the silicide film; and
a conveyer section configured to convey the substrate to the first chamber and the second chamber.

12. The apparatus of claim 11, wherein the light irradiation section is placed in the first chamber.
